(19) United States
(12) Patent Application Publication
(10) Pub. No.: US 2006/0050336 A1
(43) Pub. Date: Mar. 9, 2006

(54) TMA with film view fuction

(75) Inventor: Harn-Jou Yeh, Hsinchu (TW)

Correspondence Address: BIRCH STEWART KOLASCH & BIRCH, PO BOX 747, FALLS CHURCH, VA, 22040-0747, US

(73) Assignee: Microtek International Inc.

(21) Appl. No.: 11/127,294

(22) Filed: May 12, 2005

(30) Foreign Application Priority Data
Sep. 8, 2004 (TW) 093214306

(51) Int. Cl. G03F 3/10

(52) U.S. Cl. 358/527

(57) ABSTRACT

A TMA includes a housing, a light module and a light guide. The light module and the light guide are received in the housing. The top of the housing is provided with a preview window whose location is set corresponding to a rest position of the light module. The light guide receives the emitting light of the light module and delivers the light to the preview window.

This application claims the benefit of the filing date of Taiwan Application Ser. No. 093214306, filed on Sep. 8, 2004, the content of which is incorporated herein by reference.

### BACKGROUND OF THE INVENTION

1. Field of the Invention

The invention relates to a Transparent Media Adapter (hereinafter referred to TMA) and, more particularly, to a TMA capable of providing a light source serving for the image preview of a transparent document such as a film.

2. Description of the Related Art

A TMA is typically mounted on the scanning platform of a flatbed scanner to provide a light source used in the scanning of a transparent document. FIG. 1 shows a cross-section of a conventional TMA. Referring to FIG. 1, the TMA 10 includes a housing 12 and a movable light module 18. The TMA 10 is typically mounted on the scanning platform of a flatbed scanner (not shown), and its light module 18 is moved simultaneous with a moving frame of the scanner through the control of the scanner to provide the light source for the scanning of a transparent document. A transparent document is placed on the scanning platform of the scanner, namely between the TMA 10 and the scanning platform. Normally, the emitting light of the light module 18 penetrating a transparent glass 122 is used as the light for scanning. The light module 18 includes a reflecting mask 181, a tube lamp 182, and a diffusing plate 183. The reflecting mask 181 reflects the upwards emitting light of the tube lamp 182 to the diffusing plate 183, which uniformly spreads the incoming light to improve the utilization efficiency of the light.

Typically, a user may want to preview images on a transparent document such as a film to determine whether the film is needed to be scanned. However, the conventional TMA fails to provide the function of image preview for the transparent document, and thus the user is forced to prepare additional light sources serving for the image preview.

### SUMMARY OF THE INVENTION

In view of the aforesaid problems, an object of the invention is to provide a TMA capable of providing a light source serving for the image preview of a transparent document such as a film.

The TMA includes a housing, a light module and a light guide. The light module and the light guide are mounted in the housing. The top of the housing is provided with a preview window whose location is set corresponding to a rest position of the light module, and a user may place a film to be previewed on the preview window. The light module includes a reflecting mask, a tube lamp, and a diffusing plate. The top of the reflecting mask is provided with an opening. Before the scanner commences scanning, the light module is located on the rest position; hence, the upwards emitting light of the tube lamp may propagate in the light guide via the opening. The light guide receives the emitting light of the light module and delivers the light to the preview window.

Through the design of the invention, when the film is placed on the preview window, the emitting light of the light guide allows the user to preview the images on the film. Hence, the light source of the TMA that originally serves for the image scan may also function as a light source for the image preview of the film, and thus the user can no longer prepare additional light sources serving for the image preview of the film.

### BRIEF DESCRIPTION OF THE DRAWINGS

FIG. 1 shows a cross-section of a conventional TMA.

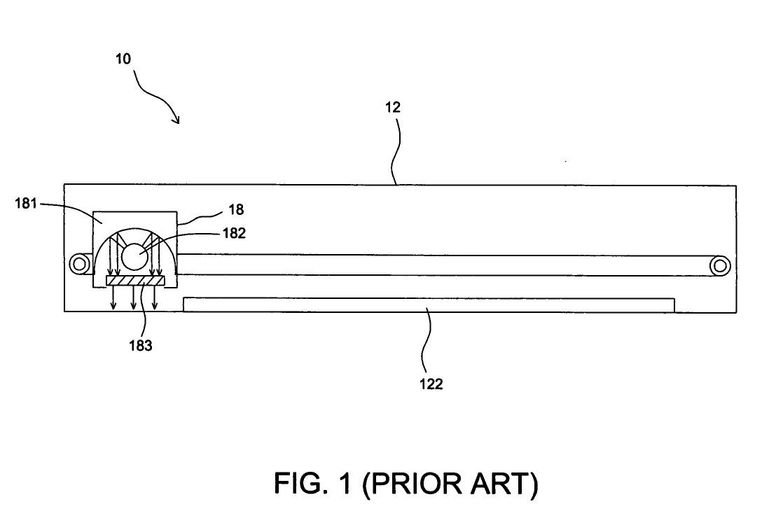

FIG. 2 shows a top view of a TMA according to the invention.

FIG. 3 shows a cross-section cut along I-I line in FIG. 2.

FIG. 4 illustrates a shape example of the opening formed on the top of the reflecting mask.

### DETAILED DESCRIPTION OF THE INVENTION

The TMA of the invention will be described with reference to the accompanying drawings.

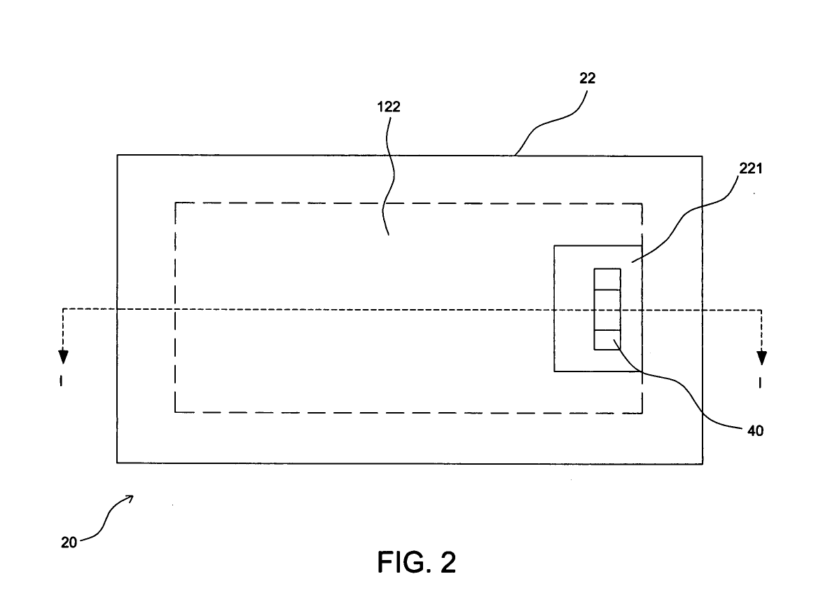

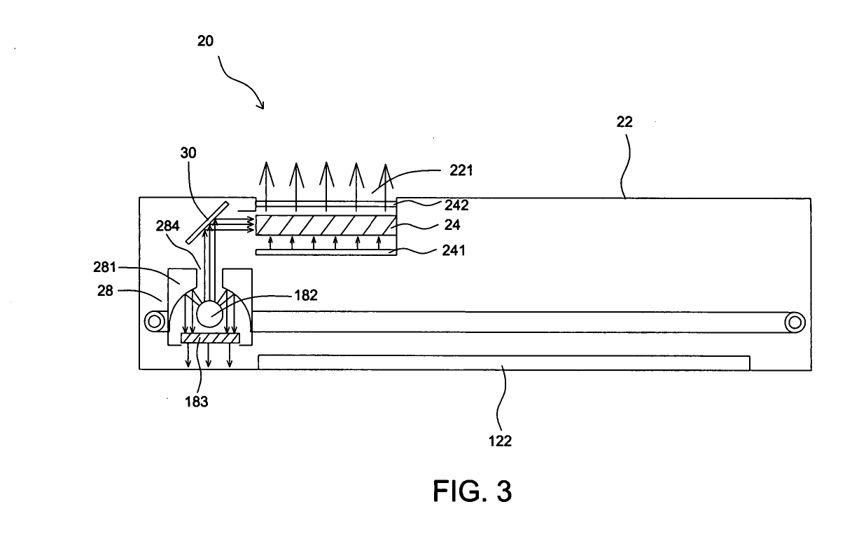

FIG. 2 shows a top view of a TMA according to the invention. FIG. 3 shows a cross-section cut along I-I line in FIG. 2. Referring to FIGS. 2 and 3, the TMA 20 includes a housing 22, a reflection mirror 30, a light guide 24, and a light module 28. The TMA 20 is typically hinged to the scanning platform of a common flatbed scanner (not shown).

Before the scanner commences scanning, the light module 28 is located on a rest position. The top of the housing 22 is provided with a preview window 221 whose location is set corresponding to the rest position of the light module 28, and a user may place a film to be previewed on the preview window 221. The preview window 221 may be a platform made of transparent glass. In this embodiment, though the preview window 221 is located near the front end of the housing 22, its location on the housing 22 is not limited. Also, the shape of the preview window 221 includes, but is not limited to, the rectangular shape as in this embodiment.

Further, the bottom of the housing 22 may be provided with a transparent glass 122 to allow the downwards emitting light of the light module 28 to penetrate there through and illuminate the scanning platform of a flatbed scanner. The installation of the light module on the flatbed scanner and how the former provides light in the later are both identical to conventional designs, thus not explaining in detail.

The light guide 24 is provided under the preview window 221 to receive the emitting light of the light module 28 and then deliver the light upwards to penetrate the preview window 221, so that the emitting light of the light guide 24 may allow the user to preview the images on a film 40 after it is placed on the preview window 221.

The light module 28 includes a reflecting mask 281, a tube lamp 282, and a diffusing plate 283. The top of the reflecting mask 281 is provided with an opening 284. Before the scanner commences scanning, the light module 28 is located on the rest position; hence, the upwards emitting light of the tube lamp 182 may propagate in the light guide 24 via the opening 284. In other words, when the light module 28 is located on the rest position, its emitting light also serves as the light source for the image preview of the film 40.

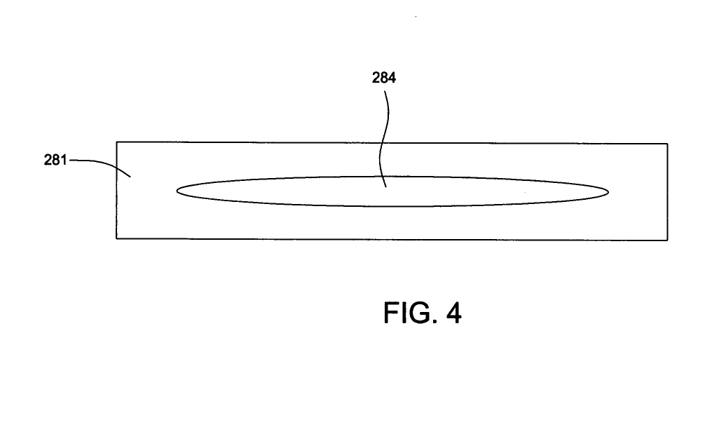

FIG. 4 illustrates a shape example of the opening 284 formed on the top of the reflecting mask 281. Referring to FIG. 4, the opening 284 is in the shape of a human eye, so that the downward reflection intensity of the reflecting mask 281 in its central location is lower compared to its two ends.

In this embodiment, the TMA 20 may further include a reflection mirror 30 tilting relative to the light guide 24 at a selected angle such as 45 degrees, so that, when the light module 28 is located on the rest position, its emitting light is directed to the light guide 24 after reflecting off the reflection mirror 30. The tilt angle of the reflection mirror 30 includes, but is not limited to, 45 degrees, and it is selected to achieve the best reflection effect. Also, the way of directing the emitting light of the light module 28 to the light guide 24 is not limited to the use of the reflection mirror 30, but may be any modification suitable for the same purpose.

Further, in this embodiment, the TMA 20 may further include a reflection plate 241 provided under the light guide 24 and corresponding to the position of the preview window 221. The reflection plate 241 may upwards reflect the light that propagates downwards from the light guide 24 to enhance the brightness of the preview window 221. Note that the reflection plate 241 may be omitted as the brightness is sufficient.

Through the design of the invention, when the film 40 is placed on the preview window 221, the emitting light of the light guide 24 allows the user to preview the images on the film. Hence, the light source of the TMA that originally serves for the image scan may also function as a light source for the image preview of the film, and thus the user can no longer prepare additional light sources serving for the image preview of the film.

Further, a diffusing plate 242 may be provided between the light guide 24 and the preview window 221 to uniformly spread the light that propagates upwards from the light guide 24 on the preview window 221, so that the utilization efficiency of the light is improved to enhance the brightness for the image preview.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. For example, an emblem or a trademark of a company may appear neighboring the preview window of the TMA, so that it is highlighted through the illumination of the emitting light of the light guide. Therefore, the scope of the appended claims should be accorded the broadest interpretation so as to encompass all such modifications and similar arrangements.

What is claimed is:

1. A TMA capable of providing a light source serving for the image preview of a transparent document, comprising:
a housing having at least one preview window on its surface;
a light module received in the housing for illuminating light; and
a light guide received in the housing for receiving the light illuminated from the light module and delivering the light to the preview window.

2. The TMA as recited in claim 1, wherein the preview window is provided on the top surface of the housing.

3. The TMA as recited in claim 2, wherein the light module comprises:
a tube lamp; and
a reflecting mask for downwards reflecting the emitting light of the tube lamp;
wherein the reflecting mask is provided with an opening to allow the emitting light of the tube lamp to propagate upwards.

4. The TMA as recited in claim 3, wherein the light guide is provided under the preview window.

5. The TMA as recited in claim 1, further comprising a reflection mirror to direct the emitting light of the light module to the light guide.

6. The TMA as recited in claim 5, wherein the reflection mirror is located above a rest position of the light module and tilts relative to the light guide at an angle of 45 degrees.

7. The TMA as recited in claim 1, further comprising a reflection plate provided under the light guide for reflecting the light that propagates downwards from the light guide to the preview window.

8. The TMA as recited in claim 1, further comprising a diffusing plate provided between the preview window and the light guide for uniformly spreading the light propagating from the light guide.

9. The TMA as recited in claim 1, wherein the transparent document is a film.

10. The TMA as recited in claim 1, wherein the TMA is mounted on a scanning platform of a flatbed scanner.
